(19) United States
(12) Patent Application Publication
(10) Pub. No.: US 2024/0278432 A1
(43) Pub. Date: Aug. 22, 2024

(54) SYSTEMS AND METHODS FOR SURFACE FITTING, PATH PLANING, AND SURFACE PROCESSING OF AN OBJECT

(71) Applicant: Maple Advanced Robotics Inc., Richmond Hill (CA)

(72) Inventors: Xiaojia He, Toronto (CA); Yuezhi Liu, Toronto (CA); Ziren Lu, Thornhill (CA)

(73) Assignee: Maple Advanced Robotics Inc., Richmond Hill, ON (CA)

(21) Appl. No.: 18/029,192

(22) PCT Filed: Aug. 15, 2022
(86) PCT No.: PCT/CA2022/051238

§ 371 Date: Mar. 29, 2023

Related U.S. Application Data
(60) Provisional application No. 63/351,578, filed on Jun. 13, 2022.
(60) Provisional application No. 63/344,311, filed on May 20, 2022.
(60) Provisional application No. 63/341,656, filed on May 13, 2022.

(51) Int. Cl. B25J 9/16; B25J 11/00

(52) U.S. Cl. CPC B25J 9/1684; B25J 9/1653; B25J 9/1664; B25J 9/1671; B25J 11/0065

(57) ABSTRACT

Systems and methods for surface fitting of a surface of an object, for path planning, and for processing a surface of a part are disclosed. The method includes receiving, at a processor, a point cloud or a mesh of the surface; dividing, by the processor, the point cloud to a plurality of overlapping sub-patches; determining by the processor, a first Root Mean Squared Error (RMSE) of the overall surface; and in response to the first RMSE being smaller or equal to the user set RMSE, generating, by the processor, coefficients for characterizing the surface.

### CROSS-REFERENCE TO RELATED APPLICATIONS

The present application claim priority over the U.S. provisional application No. 63/341,656, entitled “SYSTEM AND METHOD FOR SURFACE FITTING FOR PROCESSING A PART”, filed on May 13, 2022, the U.S. provisional application No. 63/344,311, entitled “SYSTEM AND METHOD FOR PATH PLANING FOR SURFACE PROCESSING OF A PART”, filed on May 20, 2022, and the U.S. provisional application No. 63/351,578, entitled “SYSTEM AND METHOD FOR PROCESSING A SURFACE OF A PART”, filed on Jun. 13, 2022, the contents of which are incorporated in this disclosure in their entirety.

### FIELD

The present application relates to work part processing, in particular, to systems and methods for surface fitting for processing an object, for path planning, and for processing a surface of an object.

### BACKGROUND

To process a part, the robot platform will need to know the surface characteristics of the part, and to adapt to the surface characteristics in processing the part.

However, the existing path planning methods that rarely utilize surface fitting, and often suffer flaws of the existing surface fitting algorithm when dealing with large and complex surfaces. As well, existing methods often use computationally intensive iterative algorithm, which are often impractical in actual engineering applications. Existing surface fitting methods, such as spline methods, are either inaccurate to characterize the surface without causing stability issues or only piece-wise smooth.

As well, the majority of existing path planning methods calculate the surface normal by using the orientation of the triangle within triangle mesh. The triangle mesh information construction is time consuming, especially for dense point cloud.

The existing method cannot calculate waypoints and their trajectory properties from point cloud directly, as mesh construction algorithm is very computational intense for high density point cloud data.

The accuracy of the existing methods using triangle mesh depends on the density of the mesh. This increases the calculation time if higher accuracy is required. Due to prohibitive computational costs, waypoints are often obtained manually using 3D software by creating intersection curves from the intersections of the part CAD model and planes generated by the user. For example, traditional Robot Programming Sanding Path Generation Process involves CAD software such as SolidEdge and RoboDK Software to design the path, and the designed path is manually loaded to the robot control to execute the processing application. The disadvantage of the existing methods is that the CAD model can be different from the actual work piece and thus may yield less accurate results. The subsequent path designing cannot entirely compensate the difference.

As well, the conventional path design uses sharp angle for the turning. This often cause the robotic arm to vibrate during the turning. Very often, this is compensated by slowing the tool speed at the turning. This increases the unnecessary work load and reduces the efficiency.

Finally, an adaptable robot platform may be used for work part processing, including surface processing applications robots for surface polishing, surface sanding. In such applications, the robot platform often involves applying force to the surface of a part.

For example, in the application for a robot to sand a surface of a work part, the contact area between the tool head of the robot platform and the part surface can directly affect the quality of the finishing product. If the contact area between the tool head and the surface is not constant, an uneven polishing track along the path can be generated on the surface of the part, and this can cause gaps or over polishing of part surface.

Traditionally, to ensuring constant contact area, a robot platform is configured to alter the path according to the surface shape. This is computationally intensive, the results may be inaccurate, and the processing quality may be unsatisfactory.

### SUMMARY

The present application provides systems and methods configured to perform automatic surface fitting. The system and method can process a free-form surface of an object. As such, the present application reduces or eliminates manual robot programing by special skill labor for surface fitting, improves the robot integration, and save operation costs.

In an aspect, there is provided a method for surface fitting of a surface of a part. The method includes receiving, at a processor, a point cloud or mesh by CAD model can generate, of the surface; dividing, by the processor, the point cloud to a plurality of overlapping sub-patches; determining by the processor, a first Root Mean Squared Error (RMSE) of the overall surface; and in response to the first RMSE being smaller or equal to the user set RMSE, generating, by the processor, coefficients for characterizing the surface.

In another aspect, the method further includes in response to the first RMSE of the overall surface being greater than the user set RMSE, further dividing, by the processor, sub-patches among the plurality of overlapping sub-patches with RMSE greater than the user set RMSE to smaller overlapping sub-patches; and determining, by the processor, a second RMSE of the overall surface; and in response to the second RMSE being smaller or equal to the user set RMSE, generating, by the processor, coefficients for characterizing the surface.

In another aspect, there is provided a system for surface fitting of a surface of a part. The system includes a processor, the processor is configured to receive, a point cloud of the surface; divide the point cloud to a plurality of overlapping sub-patches; determine a first Root Mean Squared Error (RMSE) of the overall surface; and in response to the first RMSE being smaller or equal to the user set RMSE, generate coefficients for characterizing the surface.

The present application provides an adaptable robot configured to perform waypoint configuration. In the present application, the path shape is projected on the surface function to allow more complex path design, and accurate waypoint positioning. As well, the present application uses the surface equation for point cloud of an object surface, this allows properties like tangent and normal vector of the path to be accurately determined.

The present application uses circular arc or smooth curve between two selected waypoints of two adjacent segments at the turning. This greatly reduce the arm vibration of the robot without increasing work load or decreasing efficiency.

In an aspect, there is provided a method for controlling movements of a tool on a surface of an object are disclosed. The method includes: defining, by a processor, a path shape on a working area of the surface; projecting, by the processor, the path shape to a surface representation characterizing a point cloud or mesh of the surface; selecting, by the processor, a plurality of waypoints for the tool to move in sequence along the waypoints, based on total curve length of a path defined by the plurality of waypoints; and generating, by the processor, positions and orientations of the waypoints for controlling movements of the tool along the waypoints for processing the surface.

In another aspect, there is provided a system for A system for controlling movements of a tool on a surface of an object, comprising: a processor configured to: define a path shape on a working area of the surface; project the path shape to a surface representation characterizing a point cloud or mesh of the surface; select a plurality of waypoints for the tool to move in sequence along the waypoints, based on total curve length of a path defined by the plurality of waypoints; and generate positions and orientations of the waypoints for controlling movements of the tool along the waypoints for processing the surface.

The present application also provides an adaptable robot system for processing a free-form surface of an object, which is configured to perform automatic part surface processing. The adaptable robot system may include robotic arm used in part manufacturing, such as parts used in automotive industry, aviation industry, and other industries. The present application substantially reduces force fluctuation in part surface processing, and provides more accurate control of the force applied to the surface of an object, and thus a better part surface processing quality.

In an aspect, there is provided a method for processing a surface of an object. The method includes defining, by a processor, two principal directions at each waypoint on a surface; generating, by the processor, principal radii of the surface at each waypoint; generating, by the processor, at least one of a vector of force comprising an array of force values at each waypoint or a vector of track width at the each waypoint; and causing a system, by the processor, to process the surface of the part using at least one of a vector of force or a vector of track width at the each waypoint in a path from the each waypoint to a next waypoint in sequence on the surface.

In another aspect, there is provided a system for processing a surface of an object. The system includes a processor configured to: define two principal directions at each waypoint on a surface; generate principal radii of the surface at each waypoints; generate at least one of a vector of force comprising an array of force values or a vector of track width at the each waypoint; and cause a system to process the surface of the part using at least one of a vector of force or a vector of track width at the each waypoint in a path from the each waypoint to a next waypoint in sequence on the surface.

### BRIEF DESCRIPTION OF THE DRAWINGS

Reference will now be made, by way of example, to the accompanying drawings which show example embodiments of the present application, and in which:

FIG. 1 is an exemplary diagram of a system, according to an embodiment of the present application;

FIG. 2 is a flow chart of a method implemented by the system of FIG. 1, according to an embodiment of the present application;

FIG. 3 is a diagram illustrating a point cloud generated for an exemplary object;

FIG. 4 is a diagram illustrating an example of overlapping sub-patches, according to an embodiment of the present application;

FIG. 5 is a diagram illustrating an example of overlapping areas of sub-patches of a surface of an object, according to an embodiment of the present application;

FIGS. 6A and 6B illustrate an example of surface fitting of two overlapping sub-patches of the surface in FIG. 5, according to an embodiment of the present application;

FIG. 7 is a diagram illustrating an example of further dividing a sub-patch to a plurality of sub-patches, according to an embodiment of the present application;

FIG. 8 is a flow chart of a method implemented by the system of FIG. 1, according to an embodiment of the present application;

FIG. 9A is a diagram illustrating an exemplary working area selected on point cloud of a surface, according to an embodiment of the present application;

FIG. 9B is a diagram illustrating an exemplary path on a working area, according to an embodiment of the present application;

FIG. 10 is a diagram illustrating the path shape design on a surface of an object;

FIG. 11 is a diagram illustrating the normal of the surface in FIG. 10 and the tangents of the waypoints on the 3D path of the surface in FIG. 10;

FIG. 12 is a diagram illustrating modifying a circular arc to be parabolic with a user defined error tolerance;

FIG. 13 is a flow chart of a method for processing a surface of an object implemented by the system of FIG. 1, according to an embodiment of the present application;

FIGS. 14A and 14B are diagrams illustrating two different contact widths with two different orientations of a tool head of the system in FIG. 1;

FIG. 15A illustrates an exemplary track path on a part surface when the track width is constant, according to an embodiment of the present application;

FIG. 15B illustrates an exemplary track path on a part surface with an allowed track overlap, according to an embodiment of the present application; and

FIG. 15C illustrates an exemplary track path on a part surface when the applied force is constant, according to an embodiment of the present application.

Similar reference numerals may have been used in different figures to denote similar components.

### DESCRIPTION OF EXAMPLE EMBODIMENTS

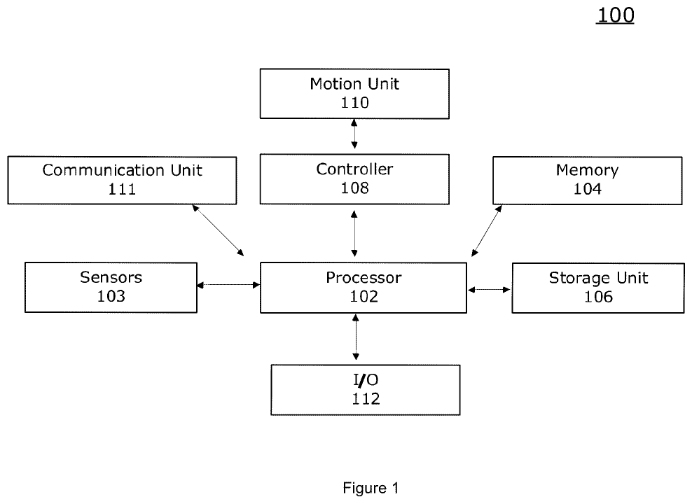

FIG. 1 illustrates an example of a system 100 the present application. The system 100 may include an adaptable robot system, such as a robotic arm used for processing work parts. Adaptable robot platform may be used for work part processing, including metal finishing robot, white light inspection robot, spray robot, etc. Robot surface processing applications include metal and composites material surface finishing. In the present application, the term “part” includes a physical object, or a part of a product, such as a vehicle, or an entire product, such as a bathtub or a toilet.

The system 100 is configured to perform various functions by installing different peripheral tools, including scanners, light curtains, spray guns, dispensing tools, and sander or polisher to the robot arms to allows fast and convenient integration. As such, the system 100 may be used to perform versatile tasks, such as metal and composite metal surface finishing, part quality inspection, laser processing, white light inspection, dispensing and spray operation, and labelling, masking and marking, by using different peripheral tools.

The system 100 may be used for surface processing applications, for example in automotive including car repairing services, car glass surface finishing, in aerospace industry, such as aviation maintenance services including gas turbine and aero engine blade surface finishing, in boating, composites manufacturing, furniture and wood manufacturing, and wind turbine manufacturing including renewable energy maintenance services.

In the example of FIG. 1, the system 100 includes a processor 102, one or more sensor 103, one or more memories 104, one or more storage units 106, and a controller 108. Although FIG. 1 shows a single instance of each component, there may be multiple instances of each component in the system 100.

The processor 102 is configured to implement the method 200 to be described below in greater detail. The processor 102 may be a central processing unit (CPU), a microprocessor, an application-specific integrated circuit (ASIC), a field-programmable gate array (FPGA), dedicated logic circuitry, or combinations thereof. The device 850 may also include one or more input/output (I/O) interfaces 854, which may enable interfacing with one or more appropriate input devices and/or output devices (not shown). One or more of the input devices and/or output devices may be included as a component of the system 100 or may be external to the system 100.

The sensors 103 are configured to detect the location information of the part in relation to the system 100, for example to detect the distances from the tools to the surface of the part, or to detect the extent of contact between the tools to the surface of the part. The sensor 103 may include one or more sensors for measuring distances or the tool head to objects in the environment such as optical sensors, acoustic sensors which operate using as such known triangulation or time-of-flight measurement (e.g. triangulation sensor, time-of-flight camera, laser range finder, ultrasonic sensors, etc.). Other suitable sensors may be cameras (in connection with image processing techniques), tactile sensors, gyroscopic sensors, etc.

The memory 104 is configured to store instructions, codes, or statements, which when executed by the processor 102, caused the processor 102 to perform predetermine functions, such as surface fitting of a part and method 200. The memory 104 may include a volatile or non-volatile memory (e.g., a flash memory, a random access memory (RAM), and/or a read-only memory (ROM)). The non-transitory memory(ies) 104 may store instructions for execution by the processor 102, such as to carry out the present disclosure. The memory(ies) 104 may include other software instructions, such as for implementing an operating system and other applications/functions. In some examples, one or more data sets and/or module(s) may be provided by an external memory (e.g., an external drive in wired or wireless communication with the system 100) or may be provided by a transitory or non-transitory computer or processor-readable medium. Examples of non-transitory computer readable media include a RAM, a ROM, an erasable programmable ROM (EPROM), an electrically erasable programmable ROM (EEPROM), a flash memory, a CD-ROM, or other portable memory storage.

In some embodiments, the memory 104 may store data used by the processor 102 to implement the methods and operations described herein, for example, point cloud or mesh data of a part surface, user input criteria including RMSE, coefficients for characterizing the surface of a part.

The storage unit 106 is configured to store data for a relevant longer period. The storage unit 106 may include a mass storage unit such as a solid state drive, a hard disk drive, a magnetic disk drive and/or an optical disk drive.

The controller 108, such as a micro controller unit (MCU), is configured to communicate with the processor 102. The processor 102 may send instructions or commands to the controller 108. In response to the instructions or commands from the processor 102, the controller 108 can be configured to send a control signal to control the motion of the system 100 via the motion unit 110. The motion unit 110 includes motors to cause the system to perform selected operations, such as processing the part.

A user may manually configure or control the system 100 via the I/O interface 112, such as a touch screen, a key board or a mouse. The I/O interface 112 may also output operation information of the system 100, for example on a display screen of the system 100.

In some examples, the system 100 may also include a communication unit 111 for a user to remotely control the system 100 via the communication unit 111.

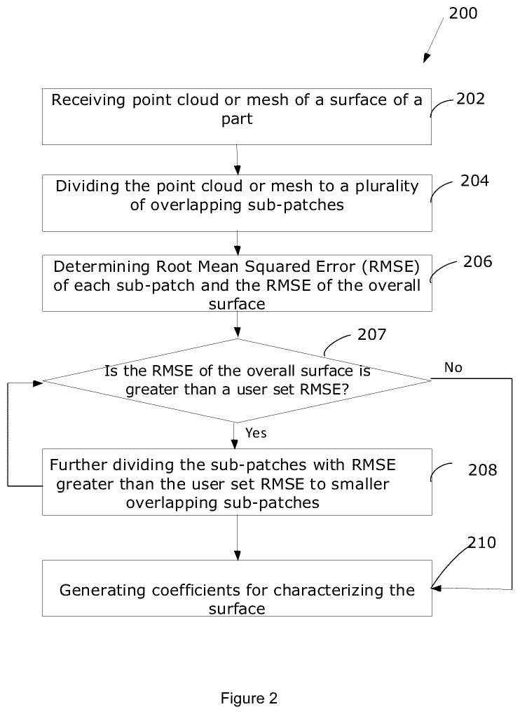

The system 100 may be configured to implement the method 200 for surface fitting of a part as illustrated in FIG. 2. In some examples, processor 102 may be configured to automatically perform surface fitting of a part for surface processing applications. The surface of the part may be a dynamic and non-repetitive surface, a free-form surface, or a surface of any form. In method 200, the processor 102 is configured to characterize the surface of a part using the scanned point cloud or mesh of the surface of a part.

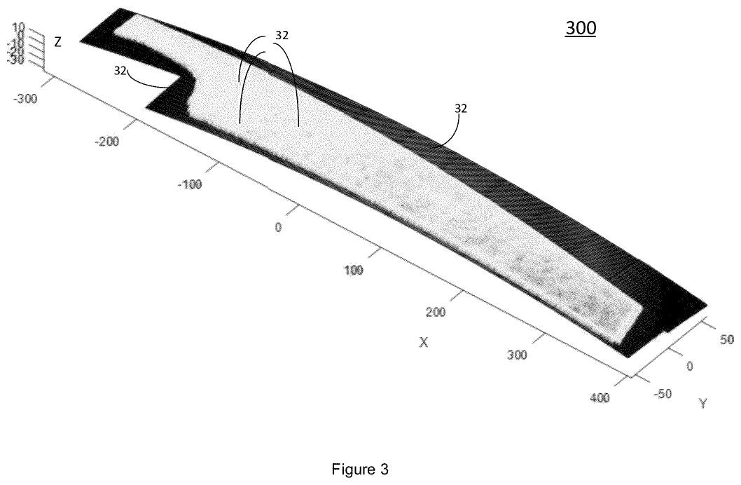

At step 202, the processor 102 is configured to receive point cloud data of the surface 500. In some examples, the processor 102 may receive mesh data of the surface 500. The mesh data of the surface 500 may be generated by Computer-Aided Design (CAD). Although point cloud is used in the examples below, the examples can also interchangeably use mesh data. The point cloud data of a surface 300 (see FIG. 3) of the part may be generate by scanning, using a scanner, a surface of a part. For example, the scanner may be mounted on the system 100 as a tool to generate point cloud. The point cloud of the surface of a part may be obtained from a vision system, for example, using a 3D camera, or an area scanner, a laser scanner.

FIG. 3 illustrates an exemplary point cloud of a part surface plotted. The example in FIG. 3 is the part of a B-pillar. In the example of FIG. 3, the shape of the B-pillar is obtained through a 3D scan. The points 32 are the point cloud scanned from a vision system. To generate the point cloud of a surface of a part, each point on the scanned surface is mapped to a selected coordinate system, and each point cloud data or points 32 on a surface contains unique the (x, y, z) coordinates in the coordinate system. The overall cloud points represent the overall scanned surface 300 of the part. Unlike the CAD model based surface fitting, the method 200 adapts the surface of a real part by scanning the surface of the part, and thus is more accurate and faster for surface fitting than CAD model based surface fitting.

At step 204, the processor 102 is configured to divide the scanned point cloud data of the surface to a plurality overlapping sub-patches. The overlapping portion of the sub-patches ensures stability and continuity of the surface fitting. As will be described below, dividing the surface into smaller sub-patches and using surface fitting mechanism to fit characterization of the surface on each sub-patch ensure the accuracy of the surface, and value on the sub-patch defined on.

The common issues of the existing surface fitting methods are that when the surface become complex, it is difficult to use one equation to accurately describe the entire surface. Using one equation to characterize a surface can cause severe inaccuracy in certain regions, and the existing surface fitting methods cannot ensure the continuity of the equations when cross from the region to another.

In method 200, the overlapping sub-patches mechanism allows stability and continuity in surface fitting. Stability leads to consistency of each fitting and continuity leads overall smoothness and hence better accuracy. Overlapping sub-patches solves discontinuity issue. By having each sub-patch overlap with adjacent sub-patches, when surface fitting algorithm is applied on each sub-patch, the adjacent sub-patches will have a common area fits into the surface characterization of both the sub-patch and the adjacent sub-patches. This ensures the continuity of the surface characterization from the sub-patch to adjacent sub-patches.

In the example of FIG. 3, the resulting point cloud is divided along the length (x-coordinate direction) by a first selected scale, such as 12, and along width (the y-coordinate direction) by a second selected scale, such as 2, with each sub-patch having an overlapping portion with the overlapping value determined by the total number of sub-patches and the surface complexity, such as 30%-50% or more overlap, of the entire area of the sub-patch. The first scale and the second scale can be same. In some other examples, the point cloud may be divided along the length and width of the point cloud, if the point cloud has a clearly defined length and width. In some other examples, the point cloud is divided into sections according to the polar coordinates, for example, when the point cloud comprises a ring shape or a substantially circular shape. In some examples, the principal component analysis can be used to categorize the point cloud shape, whether the point cloud has a clearly defined length and width or is substantially circular. For example, the shape of the point cloud can be categorized by analyzing the ratio of the length of the first and second components of the point cloud, or major and minor components of the point cloud, boundary points of the point cloud on each side of the major component axis, mid-line of the boundary points in relation to the major component axis and the straightness of the mid-line. For example, the length of the major component axis can be used to determine the general aspect ratio of the point cloud, which helps determine whether the point cloud is substantially rounded or elongated. The predetermined overlapping portion can be achieved by extending each sub-patch outward to the selected overlapping value with respect to adjacent sub-patches. Additionally, the sub-patches that cover the boundaries of the point cloud can be extended outward of the point cloud through extrapolation. Each sub-patch is fitted with a function using QR decomposition, which is a decomposition of the data matrix [symbol] of the sub-patch into a product [symbol] =QR of an orthogonal matrix Q and an upper triangular matrix R. The optimal form of the functions is determined so that the value on the sub-patch meet a predetermined criteria such as RMSE. The functions of sub-patches are then fine-tuned to ensure that the difference of the function values of the adjacent sub-patches is similar to a predetermined criteria such as RMSE over the overlapping areas.

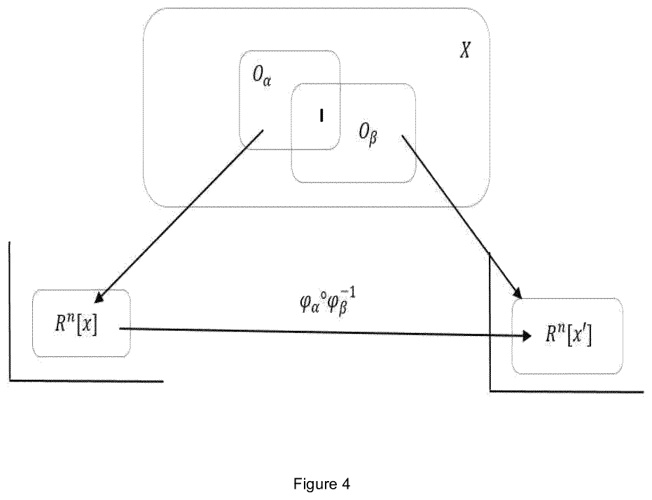

FIG. 4 illustrates an example of overlapping sub-patches of the point cloud. The overlapping sub-patches are generated based on the definition of the manifold from differential topology. In the present application, the point cloud is processed as a manifold. In the example of FIG. 4, the manifold X is a collection of subsets O_{α}, X=∪O_{α}, where O_{α}∩O_{β}≠∅. In addition, each subset is defined a coordinate mapping φ_{α}:O_{α}→Rⁿ, and at the intersection area I, φ_{α}^{o}φ_{β}⁻¹: [symbol] →Rⁿ is smooth. φ_{α}^{o}φ_{β}⁻¹: [symbol] →Rⁿ denotes coordinate transformation, where O_{α}s are the overlapping sub-patches, φ_{α}s are the surface functions φ_{α}=(x, y, z_{α}(x, y)) of the overlapping sub-patches φ_{α}s, and Rⁿ is 3D coordinate system. With respect to φ_{α}^{o}φ_{β}⁻¹, no coordinate system transformation is needed in traditional 3D coordinate system; and most commonly φ_{α}^{o}φ_{β}⁻¹ refers to a function transformation.

z_{α}(x, y) can be any type of function. For example, if a polynomial is selected for the surface function, the fitting of points represented by z_{α}(x, y) can be achieved through QR decomposition. A surface polynomial function of (x, y) with degree n, can be expressed as

$$z ( x , y ) = {\sum }_{i , j \geq 0}^{i + j \leq n} {a}_{i j} {x}^{i} {y}^{j}$$

where aᵢⱼ are coefficients describing a particular data set and can be obtained by solving a linear system in the form of

$$𝔹 a = z$$

Where [symbol] is a matrix of m×n, and the size of matrix [symbol] (m×n) depends on the degree of the polynomial n, and the size of the data set m.

With respect to φ_{α}^{o}φ_{β}⁻¹, rather than precise calculation of the transformation function to ensure smoothness when one sub-patch overlaps with the other sub-patch, it is more efficient to fine-tune the functions. For an engineering application, accuracy is more important than preciseness. Accuracy can be achieved by fine-tuning and adjusting the coefficient of the terms of the function that control the stability of the function through optimization.

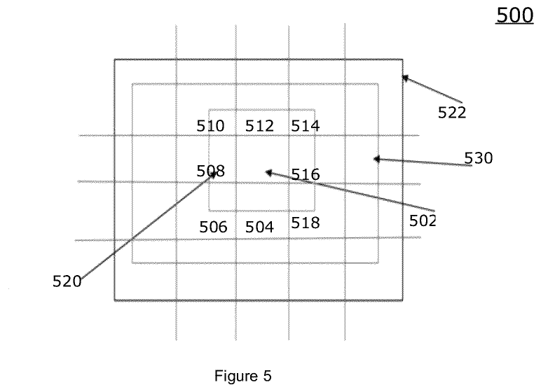

In some examples, a surface, such as a two-dimensional (2D) surface or a substantially flat surface or a three-dimensional (3D) surface, can be divided equally or unequally to a plurality sub-patches based on the total length and width of the surface. In the example of FIG. 5, a surface 500 is divided into a plurality of sub-patches, such as sub-patch 502 and adjacent sub-patches 504, 506, 508, 510, 512, 514, 516, and 518. In the example of FIG. 5, sub-patch 502 overlaps with its adjacent sub-patches 504, 506, 508, 510, 512, 514, 516, and 518 by an overlap extension, such as an overlap extension 520 between sub-patch 502 and the sub-patch 508. The surface edge 522 is extended outward, for example by using rough-fit method, to ensure the accuracy of the surface edge 522. The rough-fit method roughly fits a surface function from the whole point cloud 530, and is used to generate points to extend the edges. Iteration of the rough-fit method can be used to ensure smooth extension of the surface edge 522.

In some examples, the number of sub-patches to be divided in the point cloud of a surface, and the length and width of a sub-patch may be selected with a base number, such as 2 or 3. The base number for common shape surface can be determined experimentally. The number of sub-patches, and the length and width of a sub-patch may be gradually varied with iteration. For example, the number of the sub-patches may increase with each iteration with a selected step. The step may be a fixed step or variable step. In each iteration, the overall Root Mean Squared Error (RMSE) of the point cloud of the surface and the RMSE of each sub-patch are compared. In some examples, the RMSE of the overall surface and the sub-patches can be determined by

$$R MSE = \sqrt{\frac{{\sum }_{i = 1}^{k} {( f ( {x}_{i} , {y}_{i} ) - {z}_{i} )}^{2}}{k - 1}}$$

where (xᵢ, yᵢ, zᵢ) are the points on the sub-patch.

The number of sub-patches to be divided can be determined in view of geometry type of the surface 500. The size of the overlap can be determined to ensure stability and continuity of surface fitting. For example, the sub-patches overlap with a size provide sufficient overlap between sub-patches to ensure the stable section connection. If the overlapping areas are too big, the function may lose accuracy on the sub-patch. If RMSE of each sub-patch and the difference of the neighboring function values over the overlapping area are small enough, such as equal to or smaller than the user input RMSE, the fitted functions ensure accuracy and continuity across the entire surface. The surface fitting is optimal to ensure that best degree of a polynomial for a sub-patch is used for both accuracy and efficiency.

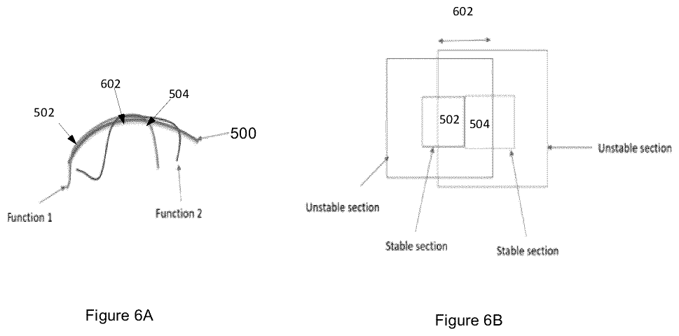

As illustrated in the examples of FIGS. 6A and 6B, sub-patch 502 can be characterized by function 1, and adjacent sub-patch 504 can be characterized by function 2, the overlapping portion 602 of sub-patches 502 and 504 fit the characterization of both sub-patches 502 and 504 and provides stable section connection between sub-patches 502 and 504. If the overlapping portion 602 is sufficiently big, as described above, the connection between sub-patches 502 and 504, including sub-patches 502 and 504, and the overlapping area 602 thereof, is stable with respect to the functions 1 and 2. Coefficients of functions or polynomials characterizing sub-patches 502 and 504 can be fine-tuned to characterize the overlapping area 602. The connection outside sub-patches adjacent to sub-patches 502 and 504 is unstable. By overlapping with adjacent sub-patches on the surface 500 of each of sub-patches 502 and 504, the connection between sub-patches 502 and 504 and adjacent sub-patches is also stable, and so forth.

If the RMSE of each sub-patch and difference of the neighboring function values over the overlapping area is small enough, such as equal to or smaller than the user input RMSE, the fitted functions ensure accuracy and continuity across the entire surface.

At steps 207, the processor 102 determines whether the RMSE of the overall surface 500 is greater than a user set RMSE.

At step 208, if the overall surface RMSE is greater than that RMSE of the user input, and a substantial portion of sub-patches, for example, over 50% of the overall sub-patches, have a RMSE greater than the RMSE of the user input, the sub-patches with RMSE greater than the user set RMSE are further divided to smaller sub-patches, for example, by reducing the area of a sub-patch, such as by reducing the length and width of a sub-patches. If the overall surface RMSE is larger than the user input RMSE, but most sub-patches, such as over 50% or more of the sub-patches, have a RMSE smaller than the RMSE of the user input, only sub-patches with RMSE greater than the user input RMSE are further divided to smaller overlapping sub-patches. The RMSE of the further divided sub-patches are then examined by the processor 102 at step 207.

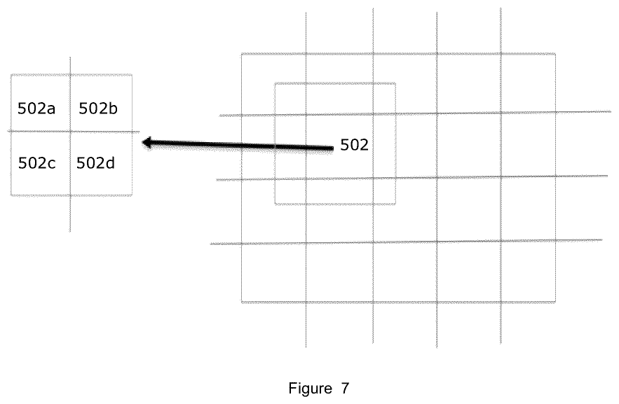

As illustrated in the example of FIG. 7, if the sub-patch 502 has a RMSE greater than the user set RMSE, the adjacent sub-patch 502 may be further divided to smaller sub-patches 502a, 502b, 502c and 502d to further reduce the differences between the RMSEs of the sub-patches 502a, 502b, 502c and 502d and the user set RMSE.

The steps 207 and 208 are complete when the overall surface RMSE is less than RMSE of the user input.

Therefore, in method 200, the number of sub-patches divided on a surface is based on the user desired accuracy requirement indicated in the user set RMSE. Further dividing a sub-patch into smaller sub-patches improves the accuracy of characterizing the surface represented by the point cloud by decreasing the RMSE of the sub-patches. Division of the sub-patches of a surface represented by point cloud as big area as possible improves efficiency of the method 200 by reducing the number of the sub-patches to be processed. As such, the method 200 characterizes the surface 500 of a part with both higher accuracy and efficiency.

At step 210, if the overall surface RMSE is smaller or equal to the RMSE of the user input, the processor 102 is configured to generate coefficients of polynomials for characterizing respective sub-patches the surface 500. The coefficients characterize the over surface 500 and each sub-patches of surface 500. The coefficients may be in the form of float or matrix. The coefficients define surface function of each sub-patch, and additional values are generated to define the boundaries of each sub-patch of surface 500. One polynomial characterized one sub-patch of the surface 500.

The processor 102 may adapt the surface characteristics in processing the part. For example, the processor 102 may use the coefficients generated in subsequent surface processing of the part, such as polishing or sanding the surface of the part. Using the coefficients, the processor 102 is configured to generate instructions or command to control the controller 108 to process the surface of a part. As method 200 characterizes the surface 500 of a part with both high accuracy and efficiency, method 200 also improves the surface processing quality due to the accuracy of the surface characterization and the improve the efficiency of the surface processing as few sub-patches as possible are to be processed.

In the case of a complex 3D surface, the surface needs to be first transformed to 2D surface, for example, using conformal flatted algorithm, and division is done on the new u, v coordinate. A complex 3D surface can usually be divided into different working areas by the user. The transformed 2D surface may be characterized by method 200 described above.

As described above, the method 200 in the present application uses overlapping surface fitting. The surface accuracy and curve accuracy with the method 200 can be in the order of up to 0.1 mm. A user may specify a lower accuracy to increase the speed of surface fitting by the processor 102. As well, the processor 102 may have a speed of 1-30 seconds, for most common cases, 1-2 seconds for a surface fitting.

As described above, the method 800 in the present application uses overlapping surface fitting. The surface accuracy and curve accuracy with the method 200 can be in the order of up to 0.1 mm. A user may specify a lower accuracy to increase the speed of surface fitting by the processor 102. As well, the processor 102 may have a speed of 1-30 seconds, for most common cases, 1-2 seconds for a surface fitting.

In the present application, a smooth curve is a curve which is a smooth function, where the word “curve” is interpreted in the analytic geometry context. In particular, a smooth curve is a continuous map from a one-dimensional space to an n-dimensional space which on its domain has continuous derivatives up to a desired order, such as at least 3^{rd} order or higher order. A smooth surface is a surface that does not have singular points, and the surface has a unique tangent plane at every point.

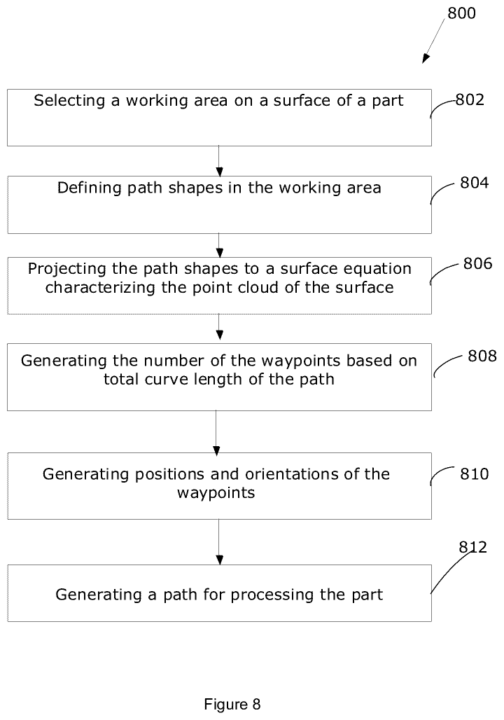

The system 100 may be configured to implement the method 800 for waypoint configuration for processing a surface of a part as illustrated in FIG. 8. In method 800, the processor 102 is configured to project path shapes on a surface function of point cloud of a part surface to allow more complex path design, and more accurate waypoint positions.

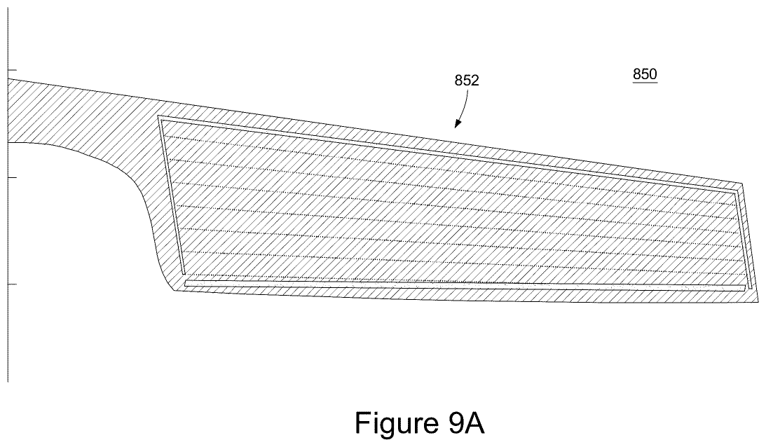

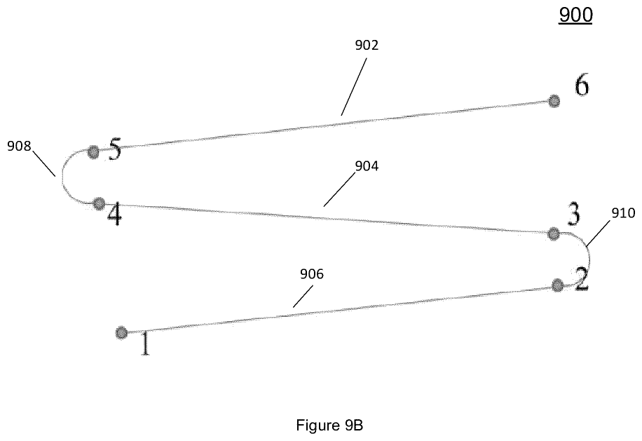

At step 802, the processor 102 is configured to select a working area on a 3-dimensional (3D) scanned point cloud of a surface of a part. For example, the working area may be defined by the point cloud data at the edge of the surface of the part. The working area may also be manually defined on the scanned point cloud by a user. For example, the user may select points on the edge of the part. In the example of FIG. 9A, a user may define a working area 852 on the surface 850 of a part.

At step 804, the processor 102 is configured to receive a path shape definition for a part surface. The path shape definition includes points selected on the point cloud of the surface. The points are point cloud data. From the points that marks the boundary, types of lines are determined by the sequence of the points.

A path shape may be defined by the user. The user may define shapes of paths based on processing requirements. The path shape is determined by the locations of points that mark the boundary of the working area. The user may select the type of the line connection, such as u-shape, round corner, or zigzag, and number of the lines to fill in the selected working area 852. The space of the lines may be substantially even and configured to partially or entirely cover the surface of the part by the tool mounted on the system 100. In some examples, in an auto path generation application. the processor 102 may also be configured to define path shapes based on the shape and the processing requirements based on the same or similar part surfaces s processed previously.

In some examples, in a manual path generation application, the user designs a path shape on a 2D surface. The user may select, for example, by clicking with a mouse, a plurality of points of the point cloud in sequence, or manual input the positions of the points in sequence. The points are connected with selected shapes of lines to connect the selected points. The user may select the type of the line connections such as, u-shape, round corner, or zigzag, to connect the selected points.

In the example of FIG. 9B, the designed path 900 includes alternate straight line segments and smooth curves, such as circular arcs. The designed path 900 is distributed on the selected on the points 1, 2, 3, 4, 5, and 6 at different positions on the point cloud of the working area selected on the point cloud of a part surface. The points 1, 2, 3, 4, 5, and 6 may be located close to the edges of the working area, so that the arc or smooth curve portion of the path close to the edge of the part but not cross the edge. Straight line segments 902, 904 and 906 connect points 5 and 6, 4 and 3, and 2 and 1, respectively. Every two adjacent line segments are connected with a smooth curve, including a circular arc. For example, the segments 902 and 904 are connected by the smooth curve 908, and the segments 904 and 906 are connected by the smooth curve 910.

Smooth curve reduces robotic arm vibration at turning by ensuring continuity in velocity and acceleration. By using smooth curves, such as 908 and 910 in FIG. 9B, at the turning, the method 800 significantly reduces the arm vibration of the system 100 without increasing work load or reducing efficiency of the system 100.

As well, the system 100 may store in the memory 104 or the storage unit a set of default shape database, and a set of parameters, such as tangent of waypoints and normal of the surface, for the processor 102 to adjust the variations of path configuration. The circular arc can be adjust to be parabolic like to further reduce the arm vibration at turning, as will be discussed in detail below.

With the coefficients characterizing the point cloud of the surface of a part, as described above, and with the definition of the path shapes from step 804, at step 806, the processor 102 is configured to project the path shapes to a surface equation with the coefficients characterizing the point cloud of the surface.

For example, path shapes can be expressed with equations. The equations of the path shapes can be projected onto the surface equation to derive equations for the spatial curve. The curve or arc length of the curve can be determined by the equations for the spatial curve from the differential geometry.

For example, the lines can be expressed with equations in a 2D space. For example, for a straight line, the equation is y=kx+b. The equations can then be projected onto a surface equation of the point cloud of the part surface or work area of the part surface. The surface equation may be expressed as s=(x,y,z(x,y)), z(x,y), which is the equation representing the scanned point cloud. The equation of the straight line projected onto the 3D surface is

$$c = ( x , kx + b , z ( x , kx + b ) ) \qquad ( 1 )$$

and the curve or arc length can be derived by

$$\int \vert ( 1 , k , \frac{d z}{d x} ) \vert d x$$

The curve or arc length can also be derived with similar approximation algorithms.

At step 808, the processor 102 is configured to determine the number of the waypoints based on total curve or arc length of the path. The spacing of the waypoints, on the actual path, such as path 900, may be determined based on the curve or arc length of the smooth curves, such as curves 908 and 910. In path 900, points 1-6 (shape points) determines the general shapes of the overall path curve, and are selected based on the user defined working area, and path density. The length of the curve or arc is determined when the shape points are selected. The user or the processor 102 may use the spacing of the waypoints and total curve or arc length to determine the number of overall waypoints to generate the path 900.

For example, if the equal distance (L) spacing of the waypoints is used, the xᵢ parameter of the waypoints can be obtained by solve numerically

$$L = {\int }_{{x}_{i}}^{{x}_{i + 1}} \vert ( 1 , k , \frac{d z}{d x} ) \vert d x \qquad ( 2 )$$

Equation (2) achieves equal spacing between the lines of the path.

At step 810, the processor 102 is configured to determine positions and orientations of the waypoints. For example, the tangent vector of the path, such as path 300, at a waypoint can be determined from the equation c=(x, kx+b, z(x, kx+b) of the spatial curve described above. The normal vector of the surface may be determined from the surface equations (1) that fitted from the point cloud data or mesh with the equations, for example, by using the theory of differential geometry. The normal vector of the surface at the waypoints along the path can be used to control the orientation of the end effector, such as the tool head. The tangent vector of the path at the waypoints can be used to control the joint motion of the last joint of the system 100, i.e., the end effector such as the tool head of system 100 such as a robot. For example, if a cutting tool is attached to the end effector of a robot, and if the cutting tool needs to be pointed at various directions, such as a direction along the path, the tangent vector can be used to determine the rotation degree of the last joint from one waypoint to the next.

For example, the tangent of the path T at a waypoint (x, y, z) and the normal of the surface N can be determined, using straight line for example, as follows:

$$T = ( 1 , k , \frac{d z}{d x} ) , N = \frac{{s}_{x} \times {s}_{y}}{\vert {s}_{x} \times {s}_{y} \vert}$$

Where Sx and Sy are partial derivatives of the surface equation s=(x, y, z(x, y)).
   The tangent T and normal N can be input to the system 100 or a robot to set the operation of the robotic arm or tools.

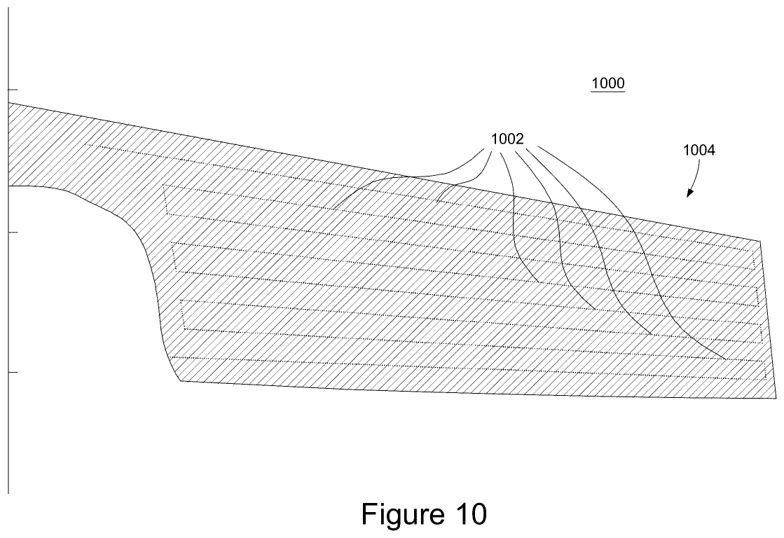

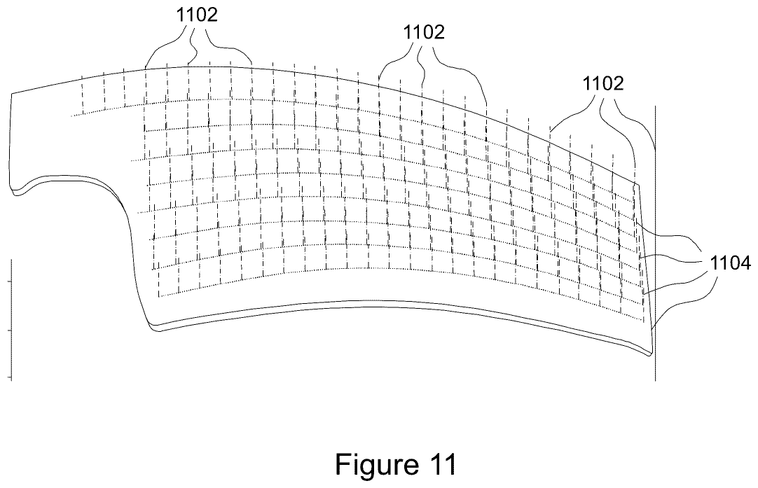

As illustrated in FIG. 10, the lines 1002 on the surface 1000 of a part indicate an outline of the path. As illustrated in FIG. 11, the waypoints on the 3D path, the lines 1102 are the normal of the surface 400 at the waypoints, and lines 1104 are the tangent of the 3D path at the waypoints on a side.

As described above, the position and orientation of the waypoints determined in step 810 provide even spacing of the waypoints based on the tool trajectory on a complex part shapes.

To determine velocity profile, arclength may be denoted as a function of time. In some examples, the arc-length may be denoted as a polynorminal function of time Lᵢ(τᵢ)=Σₙ₌₀^{m}aᵢₙTᵢτᵢⁿ, where subscript i represents the acceleration, constant velocity, and deceleration stage of the path. The velocity and acceleration are

$${\dot{L}}_{i} ( {τ}_{i} ) = {T}_{i} {\sum }_{n = 1}^{m} n {a}_{i n} {T}_{i} {τ}_{i}^{n - 1} , and {\ddot{L}}_{i} ( {τ}_{i} ) = {T}_{i}^{2} {\sum }_{n = 2}^{m} n ( n - 1 ) {a}_{i n} {T}_{i} {τ}_{i}^{n - 2}$$

By satisfying the continuity condition at the beginning and the end of each stage, the coefficients of the functions can be calculated based on the user input of velocity and acceleration requirement, so that the velocity and acceleration function are smooth along the entire path. Additionally, by using both Lᵢ(τᵢ), and the Equation (2), the waypoints with even time interval separation can be provided.

In some examples, the waypoints density on the path may be planned in proportion to the curvature density along the path. The curvature density is defined as

$$\frac{1}{L} {\int }_{{x}_{i}}^{{x}_{i + 1}} {κ}_{s} ( x ) d x$$

κₛ is the line curvature.

At step 812, based on the position and orientation of the waypoints, the processor 102 is configured to generate an operational path for the tools installed on the system 100 to operate, such as polishing or sanding, along the path on the surface of part, when the system 100 processes the part. The operational path of the tool is generated by moving the tool from one waypoint to the next waypoint in sequence. For example, the tool may move from one waypoint to the next waypoint in sequence in either a straight line or an arc. In some examples, the waypoints are connected alternately with straight line segments and smooth curves as described above. The path may be a 3D path or a 2D path.

In some examples, with respect to the smooth curve, such as u-shape or round corner, the radius of the connection curve can be determined based on the user's input on fillet radius. To turn a sharp corner into a round corner, a circle with a radius input from user on fillet radius is placed inner tangent to the two adjacent lines that makes up the sharp corner. As such, the sharp corner is removed, and replaced by the intersection points of the straight lines and circle, and the portion of the curve extended externally connects the intersection points to form a smooth curve.

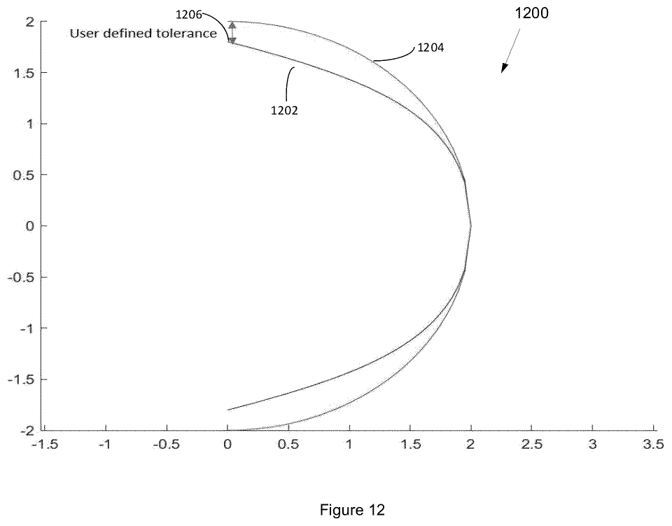

In some examples, the smooth curve such as u-shape or round corner ensures the continuity smoothness in linear velocity and acceleration. As illustrated in FIG. 12, line 1202 represents actual path on the surface of the part, which may be substantially elliptical or parabolic arc, and line 1204 represent circular arc 908 or 910 in FIG. 9B. The difference 1206 between lines 1202 and 1204 indicate the user defined error tolerance, or the error between the lines 1202 and 1204. If the user requires the continuity smoothness in angular acceleration, the circular arc and portions of the straight line near both endings can be modified to be parabolic or elliptical with based on an additional user input of error tolerance. In the case, the equation that governs the modification is parabolic in nature where the amount of modification depends on the user-defined error tolerance.

In method 800, the geometrical properties of the path can be determined analytically. As the coefficient characterizing the point cloud or mesh of the surface is accurate in that the error can be made to less than a threshold, such as 0.2 mm. As such, the path generated with method 800 is also accurate. The accuracy of the path generated may be based on the noise level of the point cloud, and the user input on desired accuracy. However, the accuracy in method 200 is not dependent on the mesh or point cloud density or smoothness.

Based on the path generated in method 800 by processor 102, the processor 102 may generate instructions or commands to control the tools installed on the system 100 to process a part surface. For example, the processor 102 may transmit the instructions or commands to the controller 108. In response, the controller 108 causes the motion unit 110 to drive the tools installed on the system 100 in accordance with the path generated. Based on the test results, with the path generated in method 800, the system 100 is faster than conventional path estimation method to process a surface part and with better accuracy or quality in processing the part surface.

As well, method 800 is configured to automatically generate a path with the user input, and is much less labor intensive than using the existing methods using CAD software.

In some examples, based on the measurement of a force sensor, compared with the result of existing methods, method 800 has only half of force fluctuation of the exiting path generating methods. This indicates that the path generated by method 200 has greater accuracy.

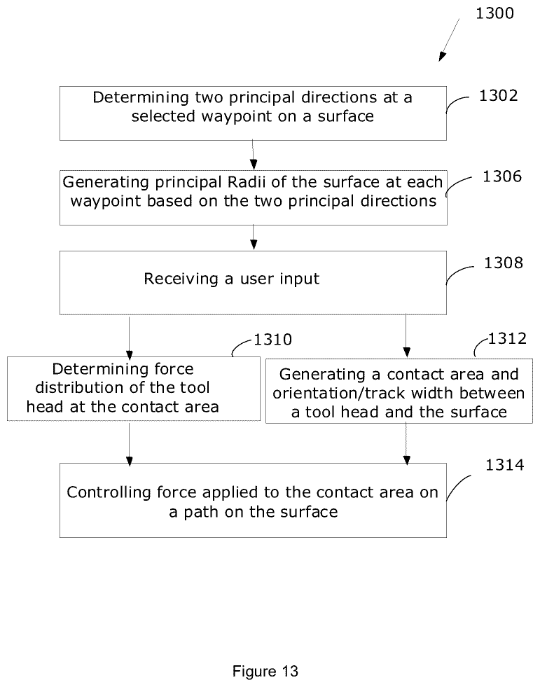

The system 100 may be configured to implement the method 1300. In method 1300, the processor 102 is configured to process a surface of a part as illustrated in FIG. 13.

Unlike traditionally approach of adjusting the contact area, the present application adjusts the force applied to a part surface or track width of the contact area between a tool head and the surface of a part. In the present application, the size of the contact area can be determined from the surface equations or coefficients characterizing the surface in a fast and accurate manner.

A surface of a part may be characterized with a plurality of coefficients. For example, the processor 102 may receive a point cloud or mesh by CAD model of the surface; divide the point cloud to a plurality of overlapping sub-patches; determine a first Root Mean Squared Error (RMSE) of the overall surface; and in response to the first RMSE being smaller or equal to the user set RMSE, generate coefficients for characterizing the surface. An example of using coefficients to characterize the point cloud or mesh data of the surface of a part is described above.

As described above, in processing a part, the processor 102 may control movements of a tool head on a surface of the part. In an example, the processor 102 may define a path shape on a working area of the surface; project the path shape to a surface representation characterizing a point cloud or mesh of the surface; select a plurality of waypoints for the tool to move in sequence along the waypoints, based on a total curve length of a path defined by the plurality of waypoints; and generate positions and orientations of the waypoints for controlling movements of the tool along the waypoints for processing the surface. An example of determining positions and orientations of the waypoints for controlling movements of a tool along the waypoints for processing the surface of a part, is described above.

In method 1300, the contact area between the tool head and the surface can be precisely determined, using the theory of differential geometry and the Hertz contact theory, and the surface characterization.

According to the Hertz theory, when two bodies are in contact, the contact area forms an ellipse. The size of the ellipse, i.e., the semi axes, can be determined from applied force, material properties, and the shapes of the part and tool head. However, the existing methods cannot accurately determine the size of the contact area, especially when the shape of the surface is complex. With the method 1300, the size and orientation of the contact area between the tool head and the surface at a waypoint, including surfaces with complex shapes, can be accurately determined, for example, using the theory of differential geometry.

To use the Hertz theory for the part surface with complex shape, the method 1300 determines the principal directions and principal radii of each waypoint on the part surface based on the surface characterization generated from the point cloud or mesh data of the part surface. Principal directions and principal radii are properties to determine the contact area between the tool and a free form surface. The principal directions determine the orientation of the contact area, and principal radii are a part of a set of parameters that determine the size and shape of the contact area.

In method 1300, to determine the principal directions and principal radii, the processor 102 is configured to represent the part surface by a continuous surface function using a plurality of coefficients. Let S=f(x, y) be the part surface function, where x and y are 2D coordinates in a Cartesian coordinates system.

In method 1300, to determine the principal radii, at step 1302 in FIG. 13, the processor 102 is configured to determine two principal directions at each waypoint on a surface. For example,

$${{{D}_{1} = \frac{d y}{d x} \vert}_{1} ( P ) and {D}_{2} = \frac{d y}{d x} \vert}_{2} ( P ) ,$$

at a waypoint P on the surface using differential geometry. D1 and D2 represent principal directions of the surface at the waypoint. The principal directions are used in the present disclosure for determining track width based on the surface fitting which characterizes the cloud point or mesh data of a surface.

In some examples, the processor 102 is configured to generate two curves having two principal directions at the each waypoint. In some examples, the tangent vectors of the two curves at waypoint P are aligned. Both curves are projected onto the x-y plane, the first curve has a tangent vector D₁ and the second curve has a tangent vector D₂. For example, the two curves can be straight lines whose projections onto the x-y plane are aligned with the principal directions D₁ and D₂. For example, the two curves can be y₁=D₁x+c₁, and y₂=D₂x+c₂. y₁ and y₂ are projected on the surface of the part. Corresponding curves of on the part surface can be expressed as follows:

$${\vec{C}}_{1} ( x ) = ( x , {y}_{1} ( x ) , f ( x , {y}_{1} ( u ) ) ) , {\vec{C}}_{2} ( x ) = ( x , {y}_{2} ( x ) , f ( x , {y}_{2} ( x ) ) )$$

where \vec{C}₁(x) and \vec{C}₂(x) are the curves on the surface of the part.

After the two curves are generated, the processor 102 is configured to determine the principal curvatures of the two curves. At step 1306, the processor 102 is configured to generate principal radii for two respectively curves. For example, κ₁(x) and κ₂(x) are the two principal curvatures derived using the theory of differential geometry. Based on principal curvatures κ₁(x) and κ₂(x), the principal radii are

$${R}_{i} ( x ) = \frac{1}{{κ}_{i} ( x )}$$

$$i = 1 , 2$$

The major principal radius can be set as the greatest radii in Rᵢ(x) value, and the minor principal radius can be set as the smallest radii in Rᵢ(x) value.

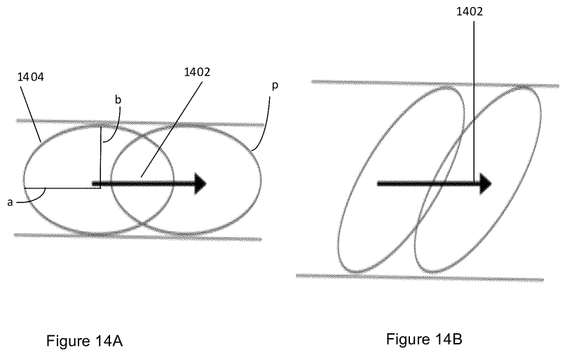

In robot polishing applications, the tool head often has a flat surface. In the examples of FIGS. 14A and 14B, the arrow 1402 indicates the direction of the motion of the tool head. Even the contact area between the tool head and the part surface may be the same, different orientation can have different contact or track width. In the waypoint application, the moving direction of the tool path when the waypoint is determined. Therefore, in the example of FIGS. 14A and 14B, the semi-axes a, the semi-major axis, and b, the semi minor axis, of the contact ellipse 1404 and the orientation of the ellipse 1404 determine the track width on path P. The semi-major axis, a, and the semi minor axis, b, are determined by a set of parameters including the principal radii of the surface, as will be described in greater detail below. The orientation of the ellipse 1404 is determined by the principal directions of the surface.

In method 1300, tool heads with special shapes, such as semi-spherical or cylindrical, can be used. On a flat surface, both major and minor principal radii are infinite. Therefore, functions of geometrical properties of the surface used in Hertz theory A and B may take the form of

$$A = \frac{1}{2 R} , B = \frac{1}{2 R}$$

Where R′ and R are the principal radii of the surface.

After A and B are determined, the semi axes a and b of the contact ellipse 1404 can be determined, for example, using Hertz theory. With the semi axes a and b, the contact ellipse 1404 and the orientation of the ellipse 1404 can also be determined based on principal directions. In the present disclosure, principal radii with applied force and values of material properties determine the semi axes a and b by applying the Hertz theory to a free form surface of the part, with the surface function that can accurately characterize a free form. Traditionally, the value of the principal radii for the free form surface is almost unobtainable except by some very computational costly procedures.

For example, according to Hertz theory, when two bodies are in contact, the maximum stress is located at the initial contact point, i.e., the center of the contact area, and the maximum stress ore pressure on the surface of the part can be related to the semi-minor axis b of the ellipse as

$${P}_{0} = \frac{b}{E ( {k}^{′} ) Δ}$$

where

$$E ( {k}^{′} ) = {\int }^{\frac{π}{0 z}} \sqrt{1 - {k}^{′2} {sin}^{2} θ} d θ$$

is a complete elliptic integral of the second kind,

$$Δ = \frac{1}{A + B} ( \frac{1 - {v}_{1}^{2}}{{E}_{1}} + \frac{1 - {v}_{2}^{2}}{{E}_{2}} ) , {k}^{′} = \sqrt{1 - {k}^{2}} ,$$

a is semi-major axis,
Eᵢ is the Young's modulus of the contacting bodies and vᵢ are their Poisson ratio, with v₁ referring to the tool head, and v₂ referring to the part surface;
A and B are functions of geometrical properties of the surface, expressed as follows:

$$A = \frac{1}{4} ( \frac{1}{{R}_{1}} + \frac{1}{{R}_{2}} + \frac{1}{{R}_{{1}^{′}}} + \frac{1}{{R}_{{2}^{′}}} ) - \frac{1}{4} \sqrt{{( ( \frac{1}{{R}_{1}} - \frac{1}{{R}_{{1}^{′}}} ) + ( \frac{1}{{R}_{2}} - \frac{1}{{R}_{{2}^{′}}} ) )}^{2} - 4 ( \frac{1}{{R}_{1}} - \frac{1}{{R}_{{1}^{′}}} ) ( \frac{1}{{R}_{2}} - \frac{1}{{R}_{{2}^{′}}} ) {sin}^{2} ϕ}$$

$$B = \frac{1}{4} ( \frac{1}{{R}_{1}} + \frac{1}{{R}_{2}} + \frac{1}{{R}_{{1}^{′}}} + \frac{1}{{R}_{{2}^{′}}} ) + \frac{1}{4} \sqrt{{( ( \frac{1}{{R}_{1}} - \frac{1}{{R}_{{1}^{′}}} ) + ( \frac{1}{{R}_{2}} - \frac{1}{{R}_{{2}^{′}}} ) )}^{2} - 4 ( \frac{1}{{R}_{1}} - \frac{1}{{R}_{{1}^{′}}} ) ( \frac{1}{{R}_{2}} - \frac{1}{{R}_{{2}^{′}}} ) {sin}^{2} ϕ}$$

where Rᵢ denotes the principal radii of the two contacting bodies, ϕ is the angle between the principal directions of the contacting bodies, and k can be determined by solving the following

$$\frac{B}{A} = \frac{\frac{1}{{k}^{2}} E ( {k}^{′} ) - K ( {k}^{′} )}{( {k}^{′} ) - E ( {k}^{′} )}$$

where K(k′) is a complete elliptic integral of the first kind, and E(k′) is a complete elliptic integral of the second kind.

At step 1308, the processor 102 is configured to receive a user input to select one of the options to process the part surface. The options include constant track width input, a constant force input, or an allowed track overlap. Alternatively, the processor 102 may receive an instructions from a user via I/O interface 112. The instructions may include one of the three options: a constant track width input, a constant force input, or an allowed track overlap. Any one of the three options applies to all types of surfaces.

At step 1310, if the option is a constant track width, or if the option is an allowed track overlap, the processor 102 is configured to generate a vector of force for the tool head to apply at each waypoint on the surface. The vector of force comprises an array of force values. For example, the processor 102 may determine the applied force vector, which includes both the direction and amount of the force, from the tool head to the part surface at each waypoint using:

$$F = \frac{2 π {b}^{3}}{3 kE ( {k}^{′} ) Δ} \qquad ( 3 )$$

The direction of the force is determined by the orientation of the waypoints. Equation (3) above indicate the relation between the force F, and the semi minor axis b. K, E(k′), Δ are functions of principal radii and material properties of the surface to processed. Semi major axis a is determined from k=b/a.

As indicated in Equation (3), b can be set as an input of a constant track width to determine the force. Alternatively, force can be set as an input of a constant force to calculate b. Alternatively, Equation (3) may be used to determine optimal force and b together based on the path shape and an allowed track overlap.

With the force vector generated, the processor 102 controls the controller 108 to control the amount of force and the direction of the force applied to the part surface at each waypoint. In some examples, if the surface is a substantially flat surface, the direction of the force on a path from a first waypoint to a second way point is the same as the orientation of the first waypoint.

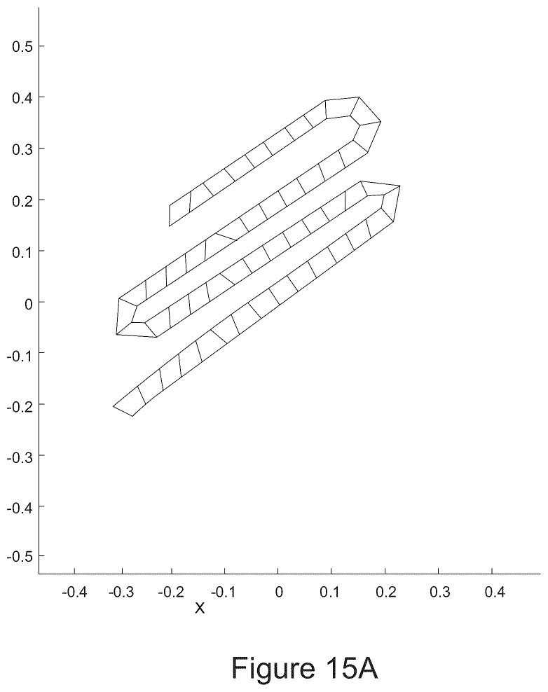

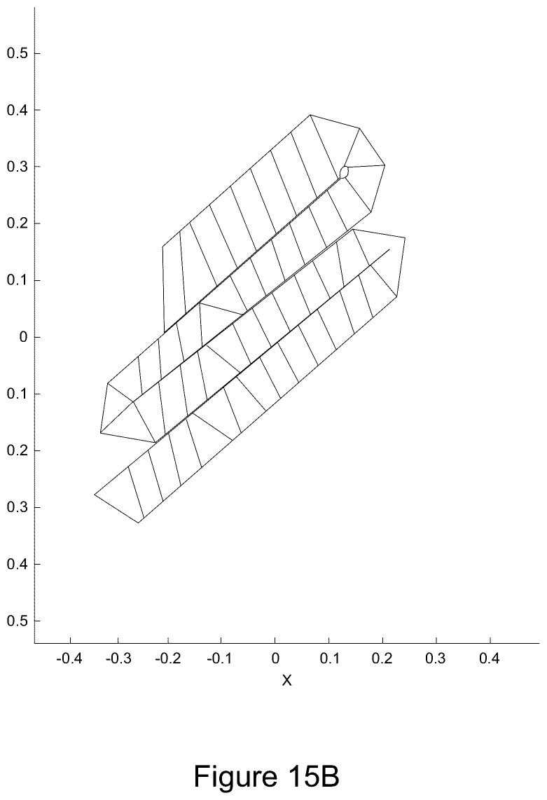

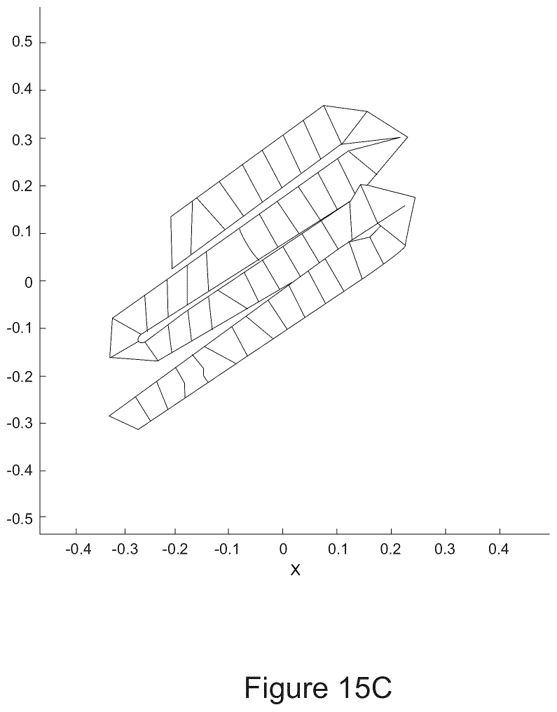

In some examples, if the system 100 has the force control capability, the processor 102 can adjust the force applied by the motion unit 110 to the tool head, the user may generate an initial path with contact track width requirement, as illustrated in the FIG. 15A, which illustrates a track path generated in a simulation when the option is a constant track width. The processor 102 may generate a force vector at step 1310. The processor 102, or the user manually, can adjust the path spacing to control the amount of force applied to the part surface. For example, if the force is excessive, for example, when the force exceeds the maximum force capable by the system 100, or the force may damage the part, the processor 102, or the user manually, can adjust, for example by reducing, the path spacing so that the tool head can apply less force on the part surface. On the other hand, if the force is insufficient for example, when the polishing track leaves gaps, the processor 102 can apply greater force on the part surface.

With the force vector determined at step 1310, the processor 102 also is configured to determine force distribution of the tool head at the contact area. For example, the processor 102 may adjust the path spacing, such as by adjusting track width to be narrower if the required force exceeds the capability of the system 100. In some examples, the processor 102 is configured to determine an appropriate track width for the force vector determined at the waypoint. In some examples, the processor 102 may generate an appropriate track width recommendation to the user for the amount of the force determined, for example, by displaying a message on the I/O 112, the user may accept the track width and manually adjust the path spacing.

FIG. 15B illustrate a track path generated in a simulation when the option is an allowed overlap. As illustrated in the example of FIG. 15B, a user may set an allowed track overlap as a percentage of the track width, for example from 5% to 30% or more, of the previous track path for processing the part surface. In response, the processor 102 may output a vector of force for applying at each waypoint. The force applies on the surface of the part from the present waypoint to a next waypoint, excluding the next waypoint. With this option, the path has no gap and the part surface is not over processed, such as over polished. In some examples, the part has curvature variation small or near flat. The system 100 does not have any risk that the force exceeds the maximum limit on the part's curvature variation is small or near flat. If the surface curvatures vary greatly and the force generated by the system 100 is insufficient to process the part surface, the processor 102 is configured to generate information, such as a warning by text message, an audible or visible signal to indicate that the force exceeds the capability of system 100.

At step 1312, if the option is a constant force input, the processor 102 is configured to generate a contact area and orientation/track width between a tool head and the surface. For example, the processor 102 is configured to generate a vector of track width at the each waypoint. The processor 102 may determine the track width with the value of the semi-minor axis b of the contact area at a waypoint as described above.

The processor 102 may use material and geometrical properties of the part surface to determine the semi-major or semi-minor axis of the contact area. As set out in Equation (1), k, E(k′), Δ are functions of principal radii and material properties.

By selecting the constant force option, the processor 102 controls the controller 108 to control the amount of force to the constant force and the direction of the force applied to the part surface at each waypoint. In some examples, the direction of the force on a path from a first waypoint to a second way point is the same as the orientation of the first waypoint.

FIG. 15C illustrates a track path generated when the option is a constant force. In FIG. 15C, the contact area between the tool and the part changes. This may result in uneven track width, which can result in unpolished gaps and lower the quality.

In some examples, the system 100 only has a constant force setting, but does not have the capability to adjust the applied force. For example, the processor 102 is not configured to adjust the force applied by the motion unit 110 to the tool head during the process of processing the part surface, such as polishing, the processor 102 or the user manually, may initially generate a path based on maximum force allowed by the system 100 or the maximum force that is safe for the part determined by the user, and to adjust the path spacing accordingly to ensure that the path does not have gap on the part surface.

As described in step 1308, the user may define or input a path shape or track width to the processor 102. If the force input by a user is a constant force in the surface processing application, the processor 102 is configured to determine a track width vector at step 1312 under the constant force at each waypoint.

In the example of FIG. 15B, the user input constant force for applying to the part surface. The processor 102 in response output a vector of track width at each waypoint. The track width applies on a segment of the surface of the part from the present waypoint to a next waypoint. With constant force, the processor 102 or the user can adjust the contact width across the surface of a part, when the system 100 does not have the capability to adjust force. In this option, the user may adjust the path of the tool head to ensure a complete coverage of the part surface.

In the example in FIG. 15A, the user input is a constant track width. The processor 102 determines the force at each waypoint using Equation (3). If the force is excessive on any waypoint, the processor 102 may generate a warning message to the user, and may provide a recommended track width based on the max force determined by the processor 102 or the user. The user may adjust the track width accordingly. In the example of FIG. 15C, the user input is a constant force, the processor 102 determines the track width at each waypoint using Equation (3). If the user uses the max force and gap still appears on the track, the processor 102 generates a recommendation of a path spacing. The user may adjust the path accordingly. In the example of FIG. 15B, the user does not input force or track width to the system 100, the user may instead input a polishing overlap value, the processor 102 determines both force and track width based on the overlap value using Equation (3). If the force is excessive at any waypoint, the processor 102 may generate a recommended path spacing to the user, and the user may adjust the path accordingly.

As well, stress distribution under the contact area on the part surface can be denoted as follows:

$$P ( {x}^{′} , {y}^{′} ) = {{P}_{0} ( 1 - {( \frac{{x}^{′}}{a} )}^{2} - {( \frac{{y}^{′}}{b} )}^{2} )}^{1 / 2} \qquad ( 4 )$$

(x′, y′) denotes the coordinate systems whose origin is placed at the point of initial contact, for example, at a waypoint. Using the above equation (4), the relation between the applied force vector and the pressure can be derived as follows

$$P = \frac{k}{E ( {k}^{′} ) Δ} {( {( \frac{3 E ( {k}^{′} ) Δ}{2 π {k}^{2}} F )}^{\frac{2}{3}} - {( {x}^{′} )}^{2} - {( \frac{{y}^{′}}{k} )}^{2} )}^{1 / 2}$$

The pressure can be used to determine effective track width. The user may define the effective edge of the track. For example, the user may set a pressure at predetermined percentage (%) of the max pressure at the center of a waypoint. If the pressure is less than a certain value, the system 100 may have insufficient material removal rate, making a polishing of a part surface ineffective. At step 1314, the processor 102 is configure to control force applied to the contact area on a path on the surface. For example, the processor 102 is configure to cause, such as by programming, the system 100 to process the surface of the part using the vector of force and/or the vector of track width in a path from the each waypoint to a next waypoint in sequence on the surface. Processing the part surface includes polishing, sanding, grinding, or carving the part surface, other applications with force of the tool head applying to the part surface. The processor 102 may control the force vector and the vector of the track width, including the amount of the force, track width, and/or the width of the track. By controlling the force and/or track width applied to the contact area between waypoints on a path on the surface, the surface of a part is processed.

When the system 100 processes the surface of the part, the track path is generated by the tool head moving along on the part surface, with the selected track width, amount of force, and direction of the force or track, as a sequence of the contact areas throughout all the waypoints on the path generated using the waypoints selected on the part surface.

In some examples, if the force or pressure to be generated exceeds the capability of the system 100, the processor 102 is configure to generate a recommendation of the modified track width vector or force vector. The user may accept or reject the recommendation.

In the example of FIGS. 15A and 15B, if the system 100 has the force control capability, the processor 102 may automatically determines the force vector of the tool head for optimal part surface processing quality.

With the method 1300, the contact area between the tool head and the surface of a part can be precisely determined by using Hertz contact theory, and differential geometry. Compared with the existing applications for controlling force on the part surface, method 1300 is numerically faster to determine the force vector of track width vector, and more accurate due to accurate surface fitting described above.

Certain adaptations and modifications of the described embodiments can be made. Therefore, the above discussed embodiments are considered to be illustrative and not restrictive.

The present disclosure provides certain example algorithms and calculations for implementing examples of the disclosed methods and operations. However, the present disclosure is not bound by any particular algorithm or calculation. Although the present disclosure describes methods and processes with steps in a certain order, one or more steps of the methods and processes may be omitted or altered as appropriate. One or more steps may take place in an order other than that in which they are described, as appropriate.

Through the descriptions of the preceding embodiments, the present invention may be implemented by using hardware only, or by using software and a necessary universal hardware platform, or by a combination of hardware and software. Based on such understandings, the technical solution of the present invention may be embodied in the form of a software product. The software product may be stored in a non-volatile or non-transitory storage medium, which can be a compact disk read-only memory (CD-ROM), USB flash drive, or a hard disk. The software product includes a number of instructions that enable a computer device (personal computer, server, or network device) to execute the methods provided in the embodiments of the present invention.

Although the present invention and its advantages have been described in detail, it should be understood that various changes, substitutions and alterations can be made herein without departing from the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for surface fitting of a surface of an object, comprising:
receiving, at a processor, a point cloud or a mesh of the surface;
dividing, by the processor, the point cloud or the mesh to a plurality of overlapping sub-patches;
determining, by the processor, a first Root Mean Squared Error (RMSE) of the overall surface;
in response to the first RMSE of the overall surface being greater than the user set RMSE, further dividing, by the processor, sub-patches among the plurality of overlapping sub-patches with RMSE greater than the user set RMSE to smaller overlapping sub-patches;
determining, by the processor, a second RMSE of the overall surface; and
in response to the second RMSE being smaller or equal to the user set RMSE, generating, by the processor, coefficients for characterizing the surface.

2. (canceled)

3. The method of claim 1, further comprising instructing, by the processor, a scanner to generate the point cloud of the surface.

4. A system for surface fitting of a surface of an object, comprising:
a processor configured to:
receive a point cloud or a mesh of the surface;
divide the point cloud or the mesh to a plurality of overlapping sub-patches;
determine a first Root Mean Squared Error (RMSE) of the overall surface;
in response to the first RMSE of the overall surface is greater than the user set RMSE, further dividing, by the processor, sub-patches among the plurality of overlapping sub-patches with RMSE greater than the user set RMSE to smaller overlapping sub-patches;
determining by the processor, a second RMSE of the overall surface; and
in response to the second RMSE being smaller or equal to the user set RMSE, generating, by the processor, coefficients for characterizing the surface.

5. (canceled)

6. A method for controlling movements of a tool on a surface of an object, comprising:
defining, by a processor, a path shape on a working area of the surface;
projecting, by the processor, the path shape to a surface representation characterizing a point cloud or mesh of the surface;
selecting, by the processor, a plurality of waypoints for the tool to move along the waypoints in sequence, based on a total curve length of a path defined by the plurality of waypoints; and
generating, by the processor, positions and orientations of the waypoints for controlling movements of the tool along the waypoints for processing the surface.

7. The method of claim 6, wherein the path shape includes alternate one or more straight line segments and smooth curves at one or more sides of the working area.

8. The method of claim 6, wherein the smooth curves comprise circular arcs.

9. The method of claim 6, wherein the positions and orientations of the plurality of waypoints are defined by tangents at the plurality of waypoints and normal of the surface.

10. The method of claim 8, further comprising modifying the circular arcs to parabolic or elliptical arcs for smoothness in an angular acceleration.

11. The method of claim 6, further comprising controlling, by the processor, the movements of the tool in a smooth linear and angular velocity, and/or in a smooth linear and angular acceleration along a path defined by the waypoints on the surface.

12. A system for controlling movements of a tool on a surface of an object, comprising:
a processor configured to:
define a path shape on a working area of the surface;
project the path shape to a surface representation characterizing a point cloud or mesh of the surface;
select a plurality of waypoints for the tool to move in sequence along the waypoints, based on total curve length of a path defined by the plurality of waypoints; and
generate positions and orientations of the waypoints for controlling movements of the tool along the waypoints for processing the surface.

13. The system of claim 12, wherein the path shape includes alternate one or more straight line segments and smooth curves at one or more sides of the working area.

14. The system of claim 12, wherein the smooth curves comprise circular arcs.

15. The system of claim 12, wherein the positions and orientations of the plurality of waypoints are defined by tangents at the plurality of waypoints and normal of the surface.

16. The system of claim 14, wherein the circular arcs are modified to parabolic or elliptical arcs for smoothness in an angular acceleration.

17. The system claim 12, the processor is configured to control the movements of the tool in a continuous linear and angular velocity, and/or in a continuous linear and angular acceleration along a path defined by the waypoints on the surface.

18-31. (canceled)
